(19) United States
(12) Patent Application Publication
(10) Pub. No.: US 2008/0063219 A1
(43) Pub. Date: Mar. 13, 2008

(54) CONTROLLING AUDIO OUTPUT OF A MOBILE TERMINAL

(75) Inventor: Taihyun Park, Gyeonggi-do (KR)

Correspondence Address: LEE, HONG, DEGERMAN, KANG & SCHMADEKA, 660 S. FIGUEROA STREET, Suite 2300, LOS ANGELES, CA, 90017, US

(73) Assignee: LG Electronics Inc.

(21) Appl. No.: 11/852,983

(22) Filed: Sep. 10, 2007

(30) Foreign Application Priority Data
Sep. 11, 2006 (KR) 10-2006-0087659

(51) Int. Cl. H03F 21/00; H03F 3/45; H03G 3/00

(52) U.S. Cl. 381/107; 330/254; 381/120

(57) ABSTRACT

A mobile terminal has an audio device to adjust the gain of an audio amplifier depending on whether the terminal is in an open or a closed position. The audio amplifier provides an audio signal to a speaker, and the volume of the audio signal is proportional to the gain of the audio amplifier. One of a plurality of gain control circuits is selected according to the position of the terminal and is provided to the audio amplifier to adjust the gain. Therefore, the gain of the audio amplifier may be greater when the terminal is in the closed position than in the open position. Alternatively, one of the gain control circuits may be selected according to a measure of the ambient noise surrounding the terminal, or may be manually selected by a user.

Pursuant to 35 U.S.C. §119(a), this application claims the benefit of earlier filing date and right of priority to Korean Patent Application No. 10-2006-0087659 filed on Sep. 11, 2006, the contents of which are hereby incorporated by reference in their entirety.

### FIELD OF THE INVENTION

This document relates to controlling audio output of a mobile terminal.

### DISCUSSION OF THE RELATED ART

As the multimedia functions of portable terminals such as portable phones, portable audio devices (PAD), and portable media players (PMP) become more popular, manufacturers tend to increase the sizes of the displays and reduce the overall size of the terminals.

In order to accommodate the opposing trends of larger displays and smaller terminals, many terminals are constructed having a main body unit and a display unit with the main body unit and the display unit interconnected with a hinge mechanism. This type of terminal is known as a folder-type terminal.

Generally, in a terminal used as a portable phone, the keypad is installed on the main body unit and is accessible to a user when the terminal is in a open position. In a closed position, the display unit is folded back on the main body unit thereby minimizing the size of the terminal.

In some terminals, a user may view a received multimedia broadcast or replays a video stored in memory by rotating the opened display unit to a horizontal position. Some audio only functions do not require viewing the display unit, and the audio only functions are operable when the terminal is in a closed position. Examples of such functions include the ring tone, replaying audio files, communicating with another terminal using a speaker-phone, etc.

When using an audio only function with the terminal is in the closed position, the speaker sound may be diminished because the speaker is shielded by another portion of the terminal. Therefore, a technique is proposed for controlling the speaker volume when the terminal is in a closed position.

FIG. 1 is a block diagram of an audio device of a conventional terminal. The conventional terminal has an audio processing unit 1 for processing an audio signal such as a voice signal, a ring tone, or music, an audio amplifier 5 for amplifying the audio signal and providing the amplified signal to a speaker (not shown), and a gain control circuit 3 for setting the gain of the audio amplifier 5.

When the folder-type terminal is closed, the audio volume is increased by using software to overcome the speaker shielding. However, when a gain of the gain control circuit 3 is fixed, the control range of the audio volume is limited because the volume is controlled by software. Also, when the output is controlled by software, a sound characteristic of the audio signal is degraded as the output increases, and consequently, the sound quality from the speaker is diminished.

### SUMMARY OF THE INVENTION

Accordingly, the present invention is directed to an audio device for a mobile terminal that substantially obviates one or more problems due to limitations and disadvantages of the related art.

An embodiment of the present invention provides an audio device in which one of several gain control circuits is selectively coupled with an audio amplifier to set the gain of the audio amplifier to control the volume of a speaker. A gain control circuit is selectively switched in response to a state, an environment, a purpose, etc. of a terminal, or may be manually selected by a user. In particular, the gain of the audio amplifier is increased when a folder-type terminal is in a closed position and decreased when the terminal is in an open position. Other factors may also be used to adjust the gain such as ambient noise, distance from a user, or a manual selection.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with a purpose of the invention, as embodied and broadly described herein, an audio device of a terminal includes an audio amplifier configured to provide an audio signal, a gain control circuit configured to control the audio amplifier gain wherein the gain control circuit comprises a plurality of resistive elements and wherein each resistive element provides a different audio amplifier gain, and a switching unit configured to connect at least one of the resistive elements to the audio amplifier to control the audio amplifier gain. The switched resistive element is connected to a differential input of the audio amplifier.

When the terminal is a folder-type terminal, the audio device further comprises a position sensor to detect whether the terminal is in an open or a closed position. The position sensor is coupled with the switching unit to select an audio amplifier gain when the terminal is in the closed position and a different gain when the terminal is in the open position. The audio amplifier gain is greater when the terminal is in the closed position than in the open position. The switching unit may also receive a manual input from a user to control the audio amplifier gain.

The audio device may further have a microphone to receive ambient noise, and a noise sensor coupled to the microphone and further coupled to the switching unit to control the amplifier gain responsive to an ambient noise level.

### BRIEF DESCRIPTION OF THE DRAWINGS

One or more implementations will be described in detail with reference to the following drawings in which like numerals refer to like elements.

FIG. 1 is a block diagram of a prior art audio device for a mobile terminal.

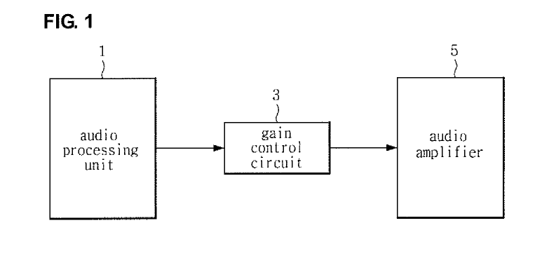

FIG. 2 is a block diagram of one embodiment of the invention of an audio device for a terminal.

FIG. 3 is a block diagram of an amplifier for the audio device.

FIG. 4 is a circuit diagram of a switch of the audio device.

### DETAILED DESCRIPTION

Embodiments of an audio device for a mobile terminal will be described in detail with reference to the accompanying drawings.

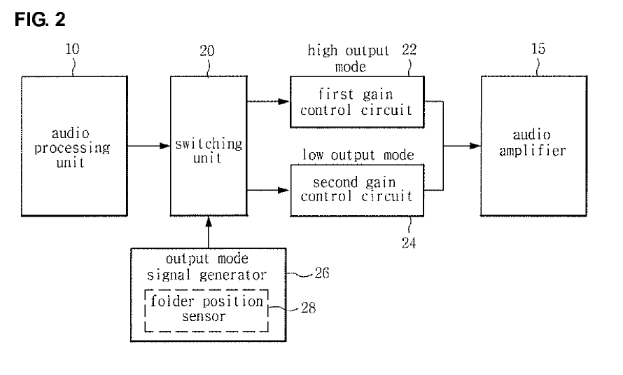

FIG. 2 is a block diagram of one embodiment of the invention of an audio device for a terminal. In particular, this drawing illustrates an example in which audio is applied to a folder type portable phone. The audio device comprises an audio processing unit 10 for processing an audio signal into an audible signal, an audio amplifier 15 for amplifying the audio signal and providing the amplified signal to a speaker, a first gain control circuit 22 and a second gain control circuit 24 for setting different gains to the audio amplifier 15, an output mode signal generator 26 for generating an audio output mode signal, and a switching unit 20 for providing the audio signal to either the first gain control circuit or the second gain control circuit according to an output mode signal.

The audio processing unit 10 processes an audio signal such as a ring tone, music, or a voice signal from a telephone call into an analog signal, and may be including in a controller of a terminal. A multimedia chipset or a codec processing other audio files may perform the function of the audio processing unit 10.

The audio amplifier 15 amplifies the audio signal received from the audio processing unit 10 to an audible level according to a specific gain, and provides the amplified signal to a speaker (not shown). The audio amplifier 15 may be constructed of various forms, such as a class-A amplifier using a bias, a class-B amplifier using a transistor, and a class-D amplifier using Pulse Width Modulation (PWM).

The first gain control circuit 22 and the second gain control circuit 24 are connected to an audio signal input terminal of the audio amplifier 15, and provide the audio signal to the audio amplifier 15 through resistors having different resistive values. The gain of the audio amplifier 15 is different depending on the amounts of resistances of the gain control circuits 22 and 24.

The first gain control circuit 22 may be constructed to provide a high gain, and can be used when a higher audio volume is required. The second gain control circuit 24 may be constructed to provide a relatively low gain, and can be used when a lower audio volume is sufficient.

The output mode signal generator 26 generates an output mode signal for selecting the first or the second gain control circuit. The output mode signal may be automatically generated depending on a use state, a use environment, a use purpose, etc. of a terminal, or may be manually selected by a user.

When the output mode signal is automatically generated, the output mode signal generator 26 comprises a sensor for sensing a state, an environment, a purpose and the like, and can generate the output mode signal based on a sensed value.

For example, when a folder-type terminal is closed, the speaker is shielded thereby degrading the audio output. The output mode signal generator 26 has a folder position sensor 28 generating a low output mode signal when the folder is open and a high output mode signal when the folder is closed to adjust the speaker volume according to the position of the terminal.

The output mode signal generator 26 may also include a noise sensor (not shown) for switching the output mode according to surrounding noise, a distance sensor (not shown) for switching the output mode according to a distance from a user, or a manual selector, etc.

The switch 20 receives the output mode signal from the output mode signal generator 26, and performs a switching operation so that the audio signal from the audio processing unit 10 is provided to the audio amplifier 15 through either the first gain control circuit 22 or the second gain control circuit 24. If the output mode signal indicates a greater speaker volume, the switch 20 directs the audio signal to the audio amplifier 15 through the first gain control circuit 22. If the output mode signal indicates a lower speaker volume, the switch 20 directs the audio signal to the audio amplifier 15 through the second gain control circuit 24.

The audio device has a plurality of the gain control circuits 22 and 24 for controlling the gain of the audio amplifier 15 thereby enabling the speaker volume to be selectively adjusted. The audio device is further configured to have the sensor for sensing an operation state, a surrounding environment, etc. of the terminal so that the output mode is automatically selected according to the sensing result. Accordingly, the audio output volume can be automatically selected according to the circumstances.

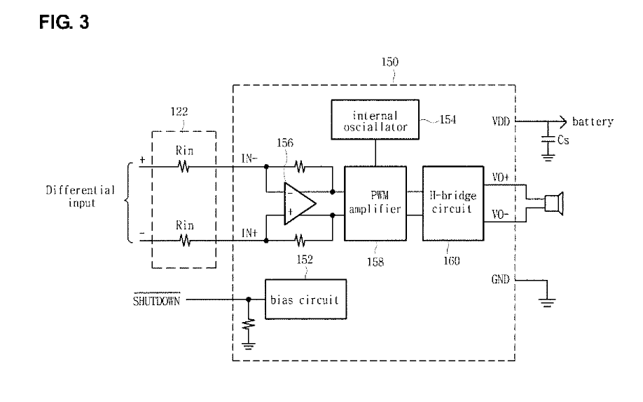

FIG. 3 is a block diagram of an audio amplifier of the audio device shown in FIG. 2. In particular, this drawing illustrates a class-D audio amplifier 150 and an input terminal 122. The class-D amp 150 comprises a comparator 156 for receiving a differential signal and providing a PWM signal, a PWM amplifier 158 for amplifying the signal from the comparator 156 according to an output frequency of an internal oscillator 154, and a H-bridge circuit 160 driven by the PWM signal output and configured to send an audio signal to the speaker through an output filter (not shown).

The input terminal of the comparator 156 is connected the gain control circuit 122. The gain of the class-D amp 150 is relative to the resistance Rᵢₙ of the gain control circuit 122. The bias circuit 152 is used to turn off or reset the class-D amp 150. The comparator 156 converts the analog audio signal, received through the gain control circuit 122, into a digital PWM signal, a sequence of pulses whose average value is directly proportional to the amplitude of the analog audio signal at that time. The PWM amplifier 158 amplifies the PWM signal from the comparator 156 to an audible level and the amplified PWM signal is sent to the speaker through the H-bridge circuit 160.

The class-D audio amplifier 150 converts the analog audio signal from the audio processing unit 10 into a pulse signal, which is then amplified through the PWM amplifier 158 to provide an audio output. The class-D audio amplifier 150 gain is controlled according to the amount of the resistance Rᵢₙ of the gain control circuit 122 connected to the differential input terminal. The first gain control circuit 22 for the high output mode (refer to FIG. 2) and the second gain control circuit 24 for the low output mode (refer to FIG. 2) provide corresponding gains of the class-D audio amplifier 150 according to the output mode signal. Thus, the audio output can be controlled using hardware.

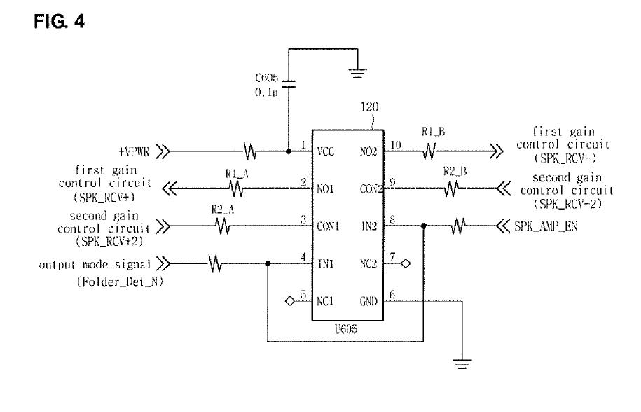

FIG. 4 is a circuit diagram of a switch of the audio device of the terminal. This drawing illustrates an example in which the gain control circuits 22 and 24 are connected to an audio amplifier by means of an analog switch 120. The analog switch 120 comprises a number of I/O ports performing a switching operation according to the output mode signal output from the output mode signal generator 26.

As an example, when the output mode signal generator 26 generates a signal responsive to the folder position sensor 28 indicating the folder-type terminal is closed, a HIGH signal is applied to port IN1 of the analog switch.

Accordingly, the analog switch 120 is connected to the audio amplifier through ports NO1 (SPK_RCV+) and NO2 (SPK_RCV−) through resistors R1_A and R1_B respectively. Thus, the audio signal output from the audio processing unit 10 is applied to the audio amplifier 150 through the resistors R1_A and R1_B. Therefore, the gain of the audio amplifier is set by the resistors R1_A and R1_B. When the folder-type terminal is closed, the volume of the audio signal is high. Accordingly, the resistors R1_A and R1_B increase the gain of the audio amplifier 150.

If the folder-type terminal is in the open position, the signal generator 26 applies a LOW signal to port IN1 of the analog switch 120. The analog switch 120 is connected to the audio amplifier through ports CON1 (SPK_RCV+2) and CON2 (SPK_RCV−2) through resistors R2_A and R2_B respectively. Thus, the audio signal output from the audio processing unit 10 is applied to the audio amplifier through the resistors R2_A and R2_B, and the gain of the audio amplifier 150 is set by resistors R2_A and R2_B. When the terminal is in an open position, resistors R2_A and R2_B decrease the gain of the audio amplifier 150.

As described above, the output mode signal for selecting the high output mode or the low output mode is applied to the control port of the analog switch 120 in order to control the connection to the audio amplifier. Resistors R1_A and R1_B, and R2_A and R2_B for controlling the amplifier gain are respectively disposed in the output port lines connected to the audio amplifier 150. Accordingly, the gain of the audio amplifier 150 can be controlled according to the audio output mode.

As described above, in accordance with embodiments of the audio device, a plurality of gain control circuits for setting the gain of the audio amplifier are provided so that the gain control circuit can be selectively adjusted responsive to a use state, a use environment, a use purpose, etc. of a terminal, or a selection by a user. Accordingly, the quality of an audio signal may be improved.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. An audio device of a terminal, the audio device comprising:
an audio amplifier configured to provide an audio signal based upon a gain value;
a plurality of gain control circuits individually configured to provide a different gain value, wherein each gain control circuit is a resistive element; and
a switching unit configured to selectively connect at least one of the gain control circuits to the audio amplifier to control the gain value responsive to a gain control selection signal.

2. The device of claim 1, wherein the at least one gain control circuit is connected to a differential input of the audio amplifier.

3. The device of claim 1, wherein the terminal is a folder-type terminal and wherein the audio device further comprises a position sensor to detect whether the terminal is in an open or a closed position.

4. The device of claim 3, wherein the position sensor is coupled with the switching unit to select a first audio amplifier gain value when the terminal is in the closed position and a second audio amplifier gain value when the terminal is in the open position.

5. The device of claim 4, wherein the first audio amplifier gain value is greater than the second audio amplifier gain value.

6. The device of claim 1, wherein the switching unit is configured to receive a manual input from a user to control the audio amplifier gain.

7. The device of claim 1, further comprising:
a microphone to receive ambient noise; and
a noise sensor coupled to the microphone and further coupled to the switching unit, wherein the noise sensor is configured to control the amplifier gain responsive to an ambient noise level.

8. A mobile terminal comprising:
an input unit configured to receive data and commands;
an audio amplifier coupled to a speaker and configured to provide an audible signal wherein the audible signal volume is proportional to a gain value of the audio amplifier;
a gain control circuit configured to control the audio amplifier gain value, wherein the gain control circuit comprises a plurality of resistive elements, and wherein each resistive element provides a different audio amplifier gain value; and
a switching unit configured to connect at least one of the resistive elements to the audio amplifier to control the audio amplifier gain value.

9. The terminal of claim 8, wherein the at least one resistive element is selectively coupled by the switching unit to a differential input of the audio amplifier.

10. The terminal of claim 8, wherein the switching unit is responsive to at least one of a position sensor, and noise sensor, and a manual input received from the input unit.

11. The terminal of claim 10, wherein the terminal is a folder-type terminal and wherein the position sensor detects whether the terminal is in an open or a closed position.

12. The terminal of claim 11, wherein the switching unit selects a first amplifier gain value when the terminal is in the closed position and a second amplifier gain value when the terminal is in the open position, and wherein the first amplifier gain value is greater than the second amplifier gain value.

13. The terminal of claim 10, further comprising a microphone coupled to the noise sensor configured to measure ambient noise, and wherein the noise sensor is coupled to the switching unit to control the amplifier gain value responsive to the ambient noise.

14. The terminal of claim 8, wherein the audio amplifier is a Pulse Width Modulation amplifier.

15. A method for controlling the volume of an audio signal of a mobile terminal, the method comprising:
selecting one of a plurality of gain control circuits responsive to one of a position sensor, a noise sensor, and a manual input received from an input unit;
applying the selected gain control circuit to an audio amplifier to determine a gain value of the audio amplifier; and
generating an audio signal comprising a volume which is proportional to the gain value of the audio amplifier.

16. The method of claim 15, wherein each gain control circuit is a resistive element, and wherein each resistive element determines a different audio amplifier gain value.

17. The method of claim 15, wherein the terminal is a folder-type terminal and wherein the position sensor detects whether the terminal is in an open or a closed position.

18. The method of claim 17, wherein a first gain control circuit determining a first audio amplifier gain value is selected when the terminal is in a closed position and a second gain control circuit determining a second audio amplifier gain value is selected when the terminal is in a closed position, and wherein the first amplifier gain value is greater than the second amplifier gain value.

19. The method of claim 15, wherein the noise sensor measures ambient noise and wherein the noise sensor selects one of the gain control circuits so that the audio amplifier gain value is greater when the ambient noise is greater.

20. The method of claim 15, wherein the audio amplifier is a Pulse Width Modulation amplifier.
